(19) United States
(12) Patent Application Publication
(10) Pub. No.: US 2007/0058346 A1
(43) Pub. Date: Mar. 15, 2007

(54) Thermal module capable of removing dust from heat sink fins by vibration and electronic device thereof

(75) Inventor: Ching-Sung Yeh, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/518,124

(22) Filed: Sep. 11, 2006

(30) Foreign Application Priority Data
Sep. 15, 2005 (TW) 094131907

(51) Int. Cl. H05K 7/20

(52) U.S. Cl. 361/697; 361/695

(57) ABSTRACT

A thermal module includes a base, a plurality of fins installed on the base, and a vibrational device installed on the base for vibrating the plurality of fins so as to remove dust from the plurality of fins. An electronic device includes a housing, and a thermal module installed inside the housing. The thermal module includes a base, a plurality of fins installed on the base, and a vibrational device installed on the base for vibrating the plurality of fins so as to remove dust from the plurality of fins.

### BACKGROUND OF THE INVENTION

1. Field of the Invention

The present invention relates to a thermal module, and more particularly, to a thermal module capable of removing dust from heat sink fins by vibration.

2. Description of the Prior Art

In modern information society, computer systems, such as desktops, notebook computers, servers, and so on, are becoming necessary. The operation speed of a typical computer is becoming faster so that the computer is utilized in a wide variety of fields. Because of the increasing speed, components of the computer generate more heat than before when processing operations. If the heat generated by the components of the computer cannot be dissipated effectively, the stability and operation speed of the computer will be reduced.

Please refer to FIG. 1. FIG. 1 is a diagram of a thermal module 12 of a notebook computer 10 of the prior art. The notebook computer 10 includes a housing 14 for covering internal components. A vent 18 is positioned on a side of the housing 14 for venting hot air from the thermal module 12 outside the housing 14. The thermal module 12 of the notebook computer 10 includes a fan 20 installed above an intake (not shown in FIG. 1), and a heat sink 22 installed between the fan 20 and the vent 18 of the housing 14. A plurality of fins 24 is installed on the heat sink 22 for increasing the heat-dissipating area. The air outside can be sucked in at the intake by the fan 20, be diffused to the plurality of fins 24 on the heat sink 22, and be vented from the vent 18 so as to dissipate heat generated by the components of the notebook computer 10 to outside the housing 14 by heat convection.

Please refer to FIG. 2. FIG. 2 is a diagram of a filter screen 26 blocking dust from getting sucked into the intake to the plurality of fins 24 by the fan 20 of the prior art. The filter screen 26 is for solving the problem of dust collecting on the fins 24, especially at the boundary between the fan 20 and the fins 24 because the dust is sucked in from the intake to the fins 24 by the fan 20. As shown in FIG. 1 and FIG. 2, the filter screen 26 is installed between the fan 20 and the fins 24 so as to prevent dust from entering the fan 20. Therefore, if a user does not clean the dust collected on the filter screen 26, the hot air cannot be vented from the vent 18 easily so that the heat generated by the components of the notebook computer 10 cannot be dissipated easily, which results in an increase of temperature in the notebook computer 10. This reduces the stability of the notebook computer 10 and the service life of the components of the notebook computer 10. However it is inconvenient for end users to disassemble the housing 14 so as to clean the filter screen 26, and many end users simply ignore the filter screen 26 installed inside the notebook computer 10.

### SUMMARY OF THE INVENTION

It is therefore a primary objective of the claimed invention to provide a thermal module capable of cleaning dust from heat sink fins by vibration for solving the above-mentioned problem.

According to the claimed invention, a thermal module includes a base, a plurality of fins installed on the base, and a vibrational device installed on the base for vibrating the plurality of fins so as to remove dust from the plurality of fins.

According to the claimed invention, an electronic device includes a housing, and a thermal module installed inside the housing. The thermal module includes a base, a plurality of fins installed on the base, and a vibrational device installed on the base for vibrating the plurality of fins so as to remove dust from the plurality of fins.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a thermal module of a notebook computer of the prior art.

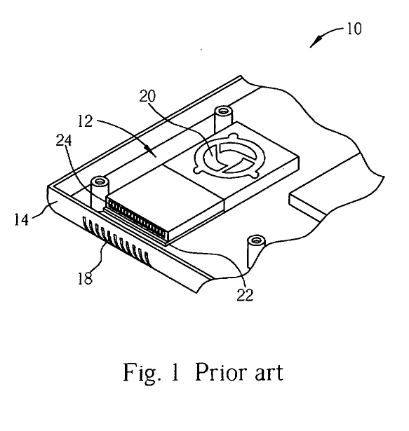

FIG. 2 is a diagram of a filter screen blocking dust from being sucked in an intake to a plurality of fins by a fan of the prior art.

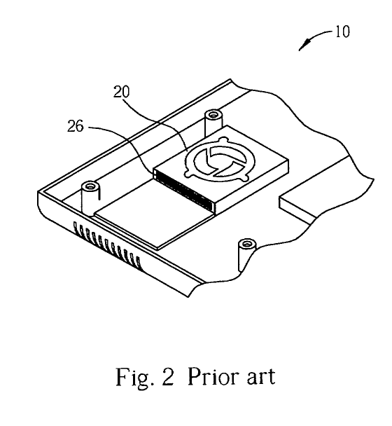

FIG. 3 is a schematic diagram of an electronic device according to an embodiment of the present invention.

FIG. 4 is a functional block diagram of the electronic device of FIG. 3 according to the embodiment of the present invention.

### DETAILED DESCRIPTION

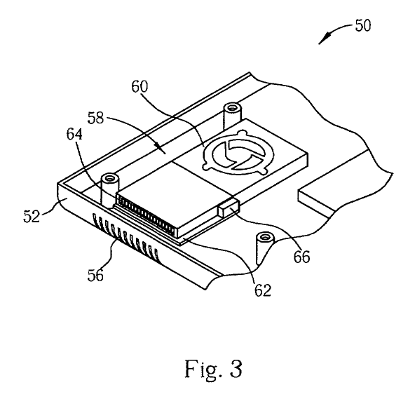

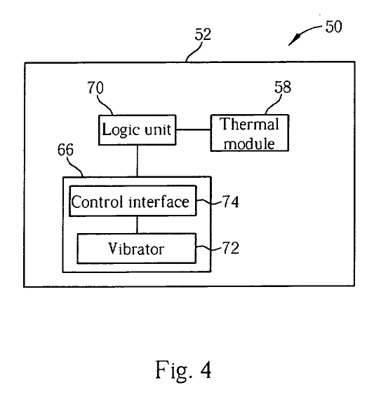

Please refer to FIG. 3. FIG. 3 is a schematic diagram of an electronic device 50 according to an embodiment of the present invention. The electronic device 50 can be a notebook computer. The electronic device 50 includes a housing 52 for covering internal components. A vent 56 is positioned on a side of the housing 52 for venting hot air. The electronic device 50 further includes a thermal module 58 including a fan 60 installed above an intake (not shown in FIG. 3) and a base 62 installed between the fan 60 and the vent 56 of the housing 52. The base can be a heat sink. A plurality of fins 64 is installed on the base 22 for increasing the heat-dissipating area. The air outside can be sucked in at the intake by the fan 60 of the thermal module 58, be diffused to the plurality of fins 64 on the base 62, and be vented from the vent 56 so as to dissipate the heat generated by the components of the electronic device 50 to outside the housing 52 by heat convection. The electronic device 50 further includes a vibrational device 66 installed on the base 62 for vibrating the plurality of fins 64 so as to remove dust from the plurality of fins 64. The vibrational device 66 can be connected to a motherboard of the electronic device 50 via a conducting wire for receiving signals and electricity. Please refer to FIG. 4. FIG. 4 is a functional block diagram of the electronic device 50 according to the embodiment of the present invention. The electronic device 50 further includes a logic unit 70, and the vibrational device 66. The vibrational device 66 includes a control interface 74 and a vibrator 72. The logic unit 70 is installed inside the housing 52 for controlling the vibrational device 66. The vibrator 72 can be vibrational motor or other vibrational component. The control interface 74 is electrically connected to the logic unit 70 and the vibrator 72 for controlling the vibrator 72 according to control signals transmitted from the logic unit 70.

The logic unit 70 can output control signals to the control interface 74 of the vibrational module 66 to turn on or turn off the vibrator 72 or to control vibrational magnitude according to current input to the vibrational module 66. For instance, after turning on the electronic device 50, the logic unit 70 turns on the fan 60 of the thermal module 58 and outputs a control signal to the control interface 74 of the vibrational module 66 for turning on the vibrator 72. Because the vibrator 72 and the fins 64 are installed on the base 62, the vibration generated by the vibrator 72 can be transmitted to the fins 64 through the base 62 so that the fins 64 vibrate corresponding to the vibrator 72. This can prevent dust from collecting on the fins 64 and can remove dust from the fins 64 by vibration. The dust on the fins 64 shaken off by the vibrator 72 can be ejected to outside the vent 56 by the fan 60. The vibrator 72 does not only prevent dust from collecting on the fins 64 so as to improve air convection but also shakes off dust already collected on the fins 64 so as to eject the dust on the fins 64 to outside the vent 54. Additionally, the embodiment of the present invention can utilize a program for controlling vibration of the vibrator 72 so that the logic unit 70 can control the vibrator 72 via the control interface 74 when executing the program. The embodiment of the present invention can also utilize a switch for controlling vibration of the vibrator 72 so that the logic unit 70 can control the vibrator 72 via the control interface 74 when the switch is switched on or off.

In contrast to the conventional electronic device, the electronic device of the embodiment of the present invention utilizes a vibrator to vibrate heat sink fins for preventing dust from collecting on the fins so as to improve air convection and removing dust collected on the fins so as to eject the dust outside the vent. This solves the inconvenience of disassembling the housing for cleaning the filter screen of the prior art. In addition, heat generated by the components of the electronic device can be dissipated easily so as to increase the stability of the electronic device and increase the service life of the components of the electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thermal module comprising:
a base;
a plurality of fins installed on the base; and
a vibrational device installed on the base for vibrating the plurality of fins so as to remove dust from the plurality of fins.

2. The thermal module of claim 1 further comprising a fan installed on a side of the plurality of fins.

3. The thermal module of claim 2 wherein the thermal module is installed inside a housing and another side of the plurality of fins is positioned corresponding to a vent of the housing.

4. The thermal module of claim 2 wherein the base is a heat sink.

5. The thermal module of claim 2 wherein the vibrational device is a vibrational motor.

6. An electronic device comprising:
a housing; and
a thermal module installed inside the housing comprising:
a base;
a plurality of fins installed on the base; and
a vibrational device installed on the base for vibrating the plurality of fins so as to remove dust from the plurality of fins.

7. The electronic device of claim 6 wherein the thermal module further comprises a fan installed on a side of the plurality of fins.

8. The electronic device of claim 7 wherein the housing comprises a vent and another side of the plurality of fins is positioned corresponding to the vent of the housing.

9. The electronic device of claim 6 wherein the base is a heat sink.

10. The electronic device of claim 6 wherein the vibrational device is a vibrational motor.

11. The electronic device of claim 6 further comprising a logic unit installed inside the housing for controlling the vibration of the vibrational device.
